(19) United States
(12) Patent Application Publication
(10) Pub. No.: US 2025/0169106 A1
(43) Pub. Date: May 22, 2025

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Ta-Chun LIN, Hsinchu (TW); Hsin-Huang LIN, Taichung City (TW); Yi-Ren CHEN, Taoyuan City (TW); Che-Chia CHANG, Hsinchu City (TW); Chun-Sheng LIANG, Changhua County (TW); Da-Zhi ZHANG, New Taipei City (TW); Chung-Yu CHIANG, Changhua County (TW); Hsiao-Han LIU, Miaoli County (TW); Po-Nien CHEN, Miaoli County (TW); Chih-Hao CHANG, Chu-Bei City (TW)

(21) Appl. No.: 18/512,339

(22) Filed: Nov. 17, 2023

(51) Int. Cl. H01L 29/417; H01L 21/8238; H01L 27/092; H01L 29/06; H01L 29/423; H01L 29/66; H01L 29/775

(52) U.S. Cl. CPC H10D 30/6729; H10D 30/014; H10D 30/43; H10D 30/6735; H10D 62/121; H10D 64/017; H10D 84/0167; H10D 84/017; H10D 84/038; H10D 84/85

(57) ABSTRACT

Semiconductor structures and methods for manufacturing the same are provided. The method includes nanostructures formed over a substrate, and a gate structure formed on the nanostructures. The semiconductor structure includes a source/drain (S/D) structure formed adjacent to the gate structure. The semiconductor structure includes a contact structure formed on the S/D structure, and a portion of the contact structure is embedded in the S/D structure, and the contact structure has a T-shaped structure.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). However, integration of fabrication of the multi-gate devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIGS. 1A to 1E illustrate perspective views of intermediate stages of manufacturing a semiconductor structure in accordance with some embodiments.

FIGS. 2A-1 to 2P-1 illustrate cross-sectional representations of various stages of manufacturing the semiconductor structure shown along line A-A′ in FIG. 1E, in accordance with some embodiments.

FIGS. 2A-2 to 2P-2 illustrate cross-sectional representations of various stages of manufacturing the semiconductor structure shown along line B-B′ in FIG. 1E, in accordance with some embodiments.

FIG. 3 illustrates a cross-sectional view of a semiconductor structure along line A-A′ in FIG. 1E, in accordance with some embodiments.

FIG. 4 illustrates a cross-sectional view of the semiconductor structure along line B-B′ in FIG. 1E, in accordance with some embodiments.

FIG. 5 illustrates a cross-sectional view of a semiconductor structure, in accordance with some embodiments.

FIG. 6 illustrates a cross-sectional view of a semiconductor structure, in accordance with some embodiments.

FIGS. 7A-1 to 7D-1 illustrate cross-sectional representations of various stages of manufacturing a semiconductor structure shown along line A-A′ in FIG. 1E, in accordance with some embodiments.

FIGS. 7A-2 to 7D-2 illustrate cross-sectional representations of various stages of manufacturing the semiconductor structure shown along line B-B′ in FIG. 1E, in accordance with some embodiments.

FIG. 8 illustrates a cross-sectional view of a semiconductor structure, in accordance with some embodiments.

### DETAILED DESCRIPTION

The following disclosure provides many different embodiments, or examples, for implementing different features of the subject matter provided. Specific examples of components and arrangements are described below to simplify the present disclosure.

These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The fins described below may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments of semiconductor structures and methods for forming the same are provided. The semiconductor structures may include a number of nanostructures formed over a substrate. A gate structure formed over the nanostructures and an S/D structure adjacent to the gate structure. An S/D contact structure is formed on the S/D structure, and a portion of the S/D contact structure is embedded into the S/D structure. The S/D contact structure is formed by two step etching process to form an opening and a T-shaped trench, and the materials formed in the opening and T-shaped trench. Since the/D contact structure is formed by two step etching process, the aspect ratio is recued to help the filling the contact materials. In addition, the contact area between the/D contact structure and the S/D structure is increased by forming the T-shaped structure S/D contact structure 162. The contact resistance between the S/D contact structure and the S/D structure is reduced. Therefore, the performance of the semiconductor structure is improved.

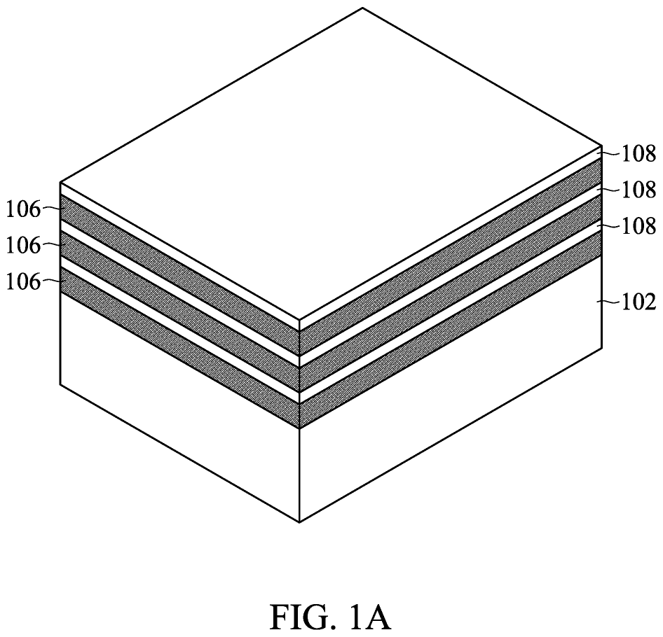

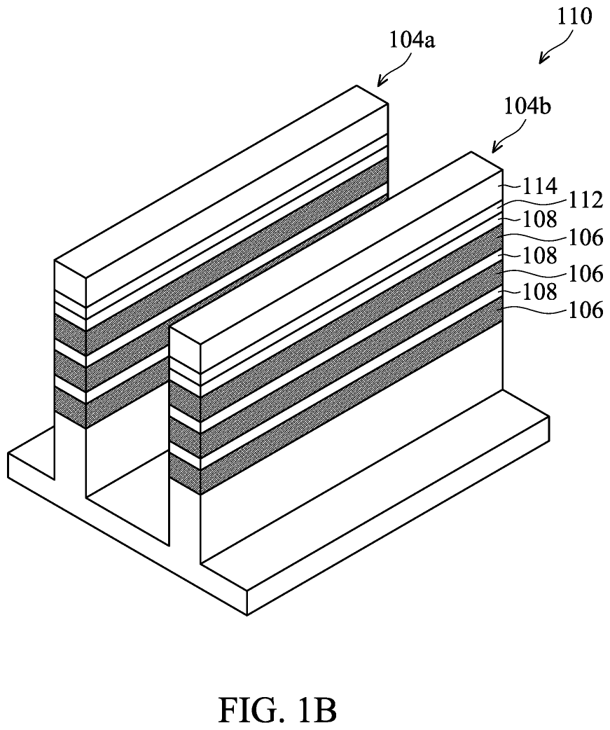

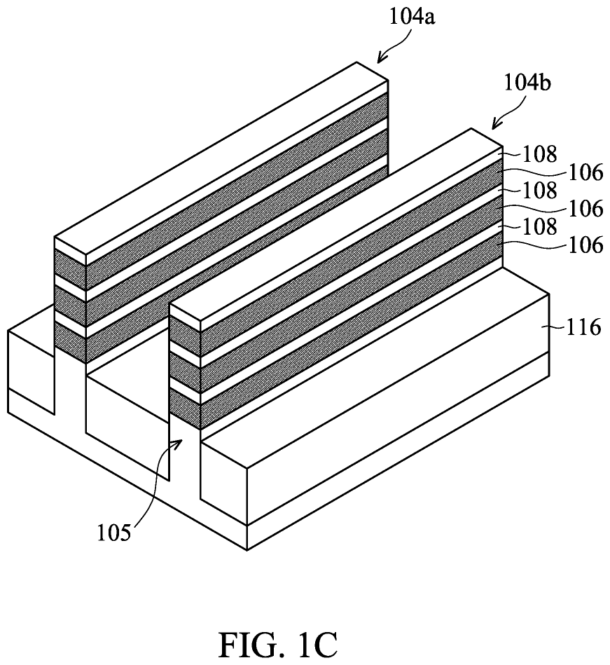

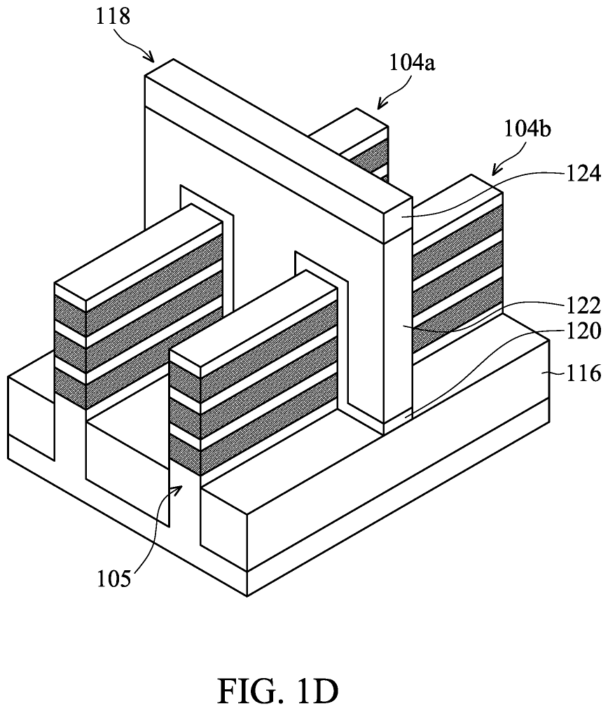

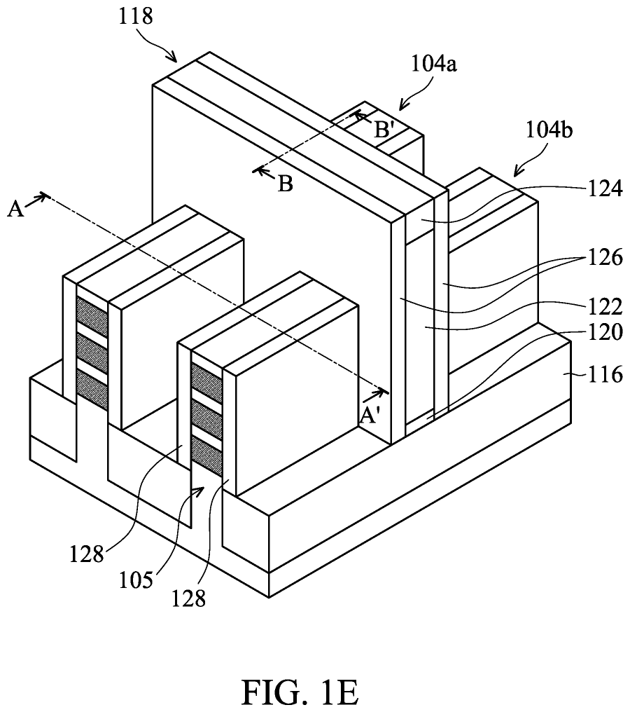

FIGS. 1A to 1E illustrate perspective views of intermediate stages of manufacturing a semiconductor structure 100a in accordance with some embodiments. As shown in FIG. 1A, first semiconductor material layers 106 and second semiconductor material layers 108 are formed over a substrate 102.

The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102. In some embodiment, the first semiconductor material layers 106 and the second semiconductor material layers 108 are made of different semiconductor materials. In some embodiments, the first semiconductor material layers 106 are made of SiGe, and the second semiconductor material layers 108 are made of silicon. It should be noted that although three first semiconductor material layers 106 and three second semiconductor material layers 108 are formed, the semiconductor structure may include more or fewer first semiconductor material layers 106 and second semiconductor material layers 108. For example, the semiconductor structure may include two to five of the first semiconductor material layers 106 and the second semiconductor material layers.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

Afterwards, as shown in FIG. 1B, after the first semiconductor material layers 106 and the second semiconductor material layers 108 are formed as a semiconductor material stack over the substrate 102, the semiconductor material stack is patterned to form a first stack structure 104a and a second stack structure 104b, in accordance with some embodiments. In some embodiments, each of the first stack structure 104a and a second stack structure 104b includes a base fin structure 105 and the semiconductor material stack of the first semiconductor material layers 106 and the second semiconductor material layers 108.

In some embodiments, the patterning process includes forming a mask structure 110 over the semiconductor material stack, and etching the semiconductor material stack and the underlying substrate 102 through the mask structure 110. In some embodiments, the mask structure 110 is a multilayer structure including a pad oxide layer 112 and a nitride layer 114 formed over the pad oxide layer 112. The pad oxide layer 112 may be made of silicon oxide, which is formed by thermal oxidation or chemical vapor deposition (CVD), and the nitride layer 114 may be made of silicon nitride, which is formed by chemical vapor deposition (CVD), such as low-temperature chemical vapor deposition (LPCVD) or plasma-enhanced CVD (PECVD).

Next, as shown in FIG. 1C, after the fin structure 104 is formed, an isolation structure 116 is formed around the fin structure 104, and the mask structure 110 is removed, in accordance with some embodiments. The isolation structure 116 is configured to electrically isolate active regions (e.g. the fin structure 104) of the semiconductor structure 100 and is also referred to as shallow trench isolation (STI) feature in accordance with some embodiments.

The isolation structure 116 may be formed by depositing an insulating layer over the substrate 102 and recessing the insulating layer so that the fin structure 104 is protruded from the isolation structure 116. In some embodiments, the isolation structure 116 is made of silicon oxide, silicon nitride, silicon oxynitride (SiON), another suitable insulating material, or a combination thereof. In some embodiments, a dielectric liner (not shown) is formed before the isolation structure 116 is formed, and the dielectric liner is made of silicon nitride and the isolation structure formed over the dielectric liner is made of silicon oxide.

Afterwards, as shown in FIG. 1D, after the isolation structure 116 is formed, dummy gate structures 118 are formed across the fin structure 104 and extend over the isolation structure 116, in accordance with some embodiments. The dummy gate structures 118 may be used to define the source/drain regions and the channel regions of the resulting semiconductor structure 100.

In some embodiments, the dummy gate structures 118 include dummy gate dielectric layers 120 and dummy gate electrode layers 122. In some embodiments, the dummy gate dielectric layers 120 are made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layers 120 are formed using thermal oxidation, chemical vapor deposition (CVD), atomic vapor deposition (ALD), physical vapor deposition (PVD), another suitable method, or a combination thereof.

In some embodiments, the conductive material includes polycrystalline-silicon (poly-Si), poly-crystalline silicon-germanium (poly-SiGe), metallic nitrides, metallic silicides, metals, or a combination thereof. In some embodiments, the dummy gate electrode layers 122 are formed using chemical vapor deposition (CVD), physical vapor deposition (PVD), or a combination thereof.

In some embodiments, hard mask layers 124 are formed over the dummy gate structures 118. In some embodiments, the hard mask layers 124 include multiple layers, such as an oxide layer and a nitride layer. In some embodiments, the oxide layer is silicon oxide, and the nitride layer is silicon nitride.

The formation of the dummy gate structures 118 may include conformally forming a dielectric material as the dummy gate dielectric layers 120. Afterwards, a conductive material may be formed over the dielectric material as the dummy gate electrode layers 122, and the hard mask layer 124 may be formed over the conductive material. Next, the dielectric material and the conductive material may be patterned through the hard mask layer 124 to form the dummy gate structures 118.

Next, as shown in FIG. 1E, after the dummy gate structures 118 are formed, gate spacer layers 126 are formed along and covering opposite sidewalls of the dummy gate structure 118 and fin spacer layers 128 are formed along and covering opposite sidewalls of the source/drain regions of the fin structure 104, in accordance with some embodiments.

The gate spacer layers 126 may be configured to separate source/drain structures from the dummy gate structure 118 and support the dummy gate structure 118, and the fin spacer layers 128 may be configured to constrain a lateral growth of subsequently formed source/drain structure and support the fin structure 104.

In some embodiments, the gate spacer layers 126 and the fin spacer layers 128 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. The formation of the gate spacer layers 126 and the fin spacer layers 128 may include conformally depositing a dielectric material covering the dummy gate structure 118, the fin structure 104, and the isolation structure 116 over the substrate 102, and performing an anisotropic etching process, such as dry plasma etching, to remove the dielectric layer covering the top surfaces of the dummy gate structure 118, the fin structure 104, and portions of the isolation structure 116.

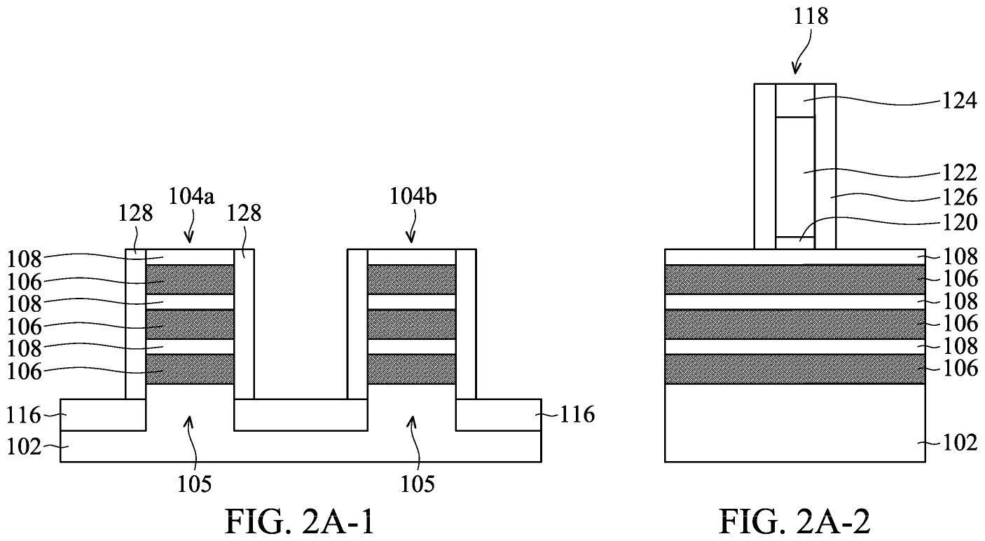

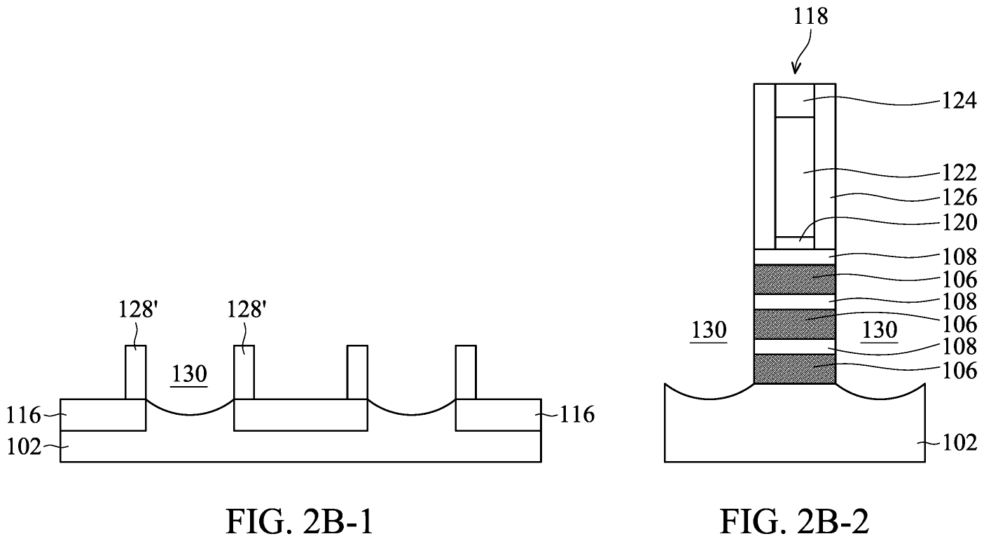

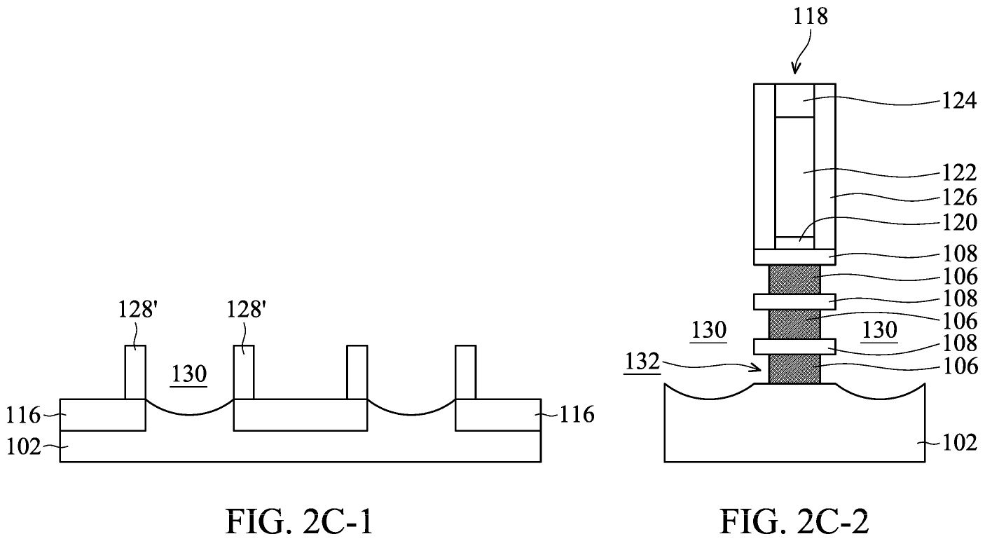

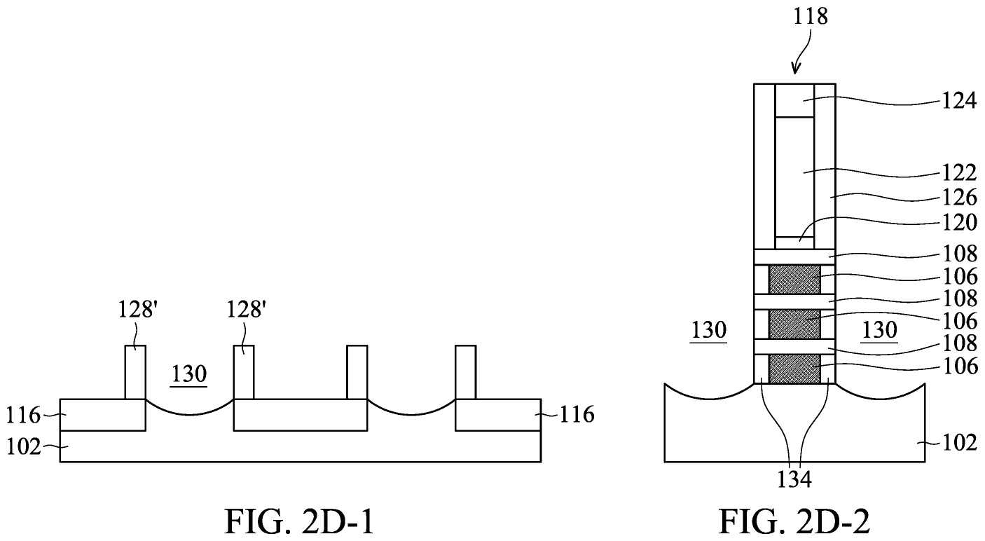

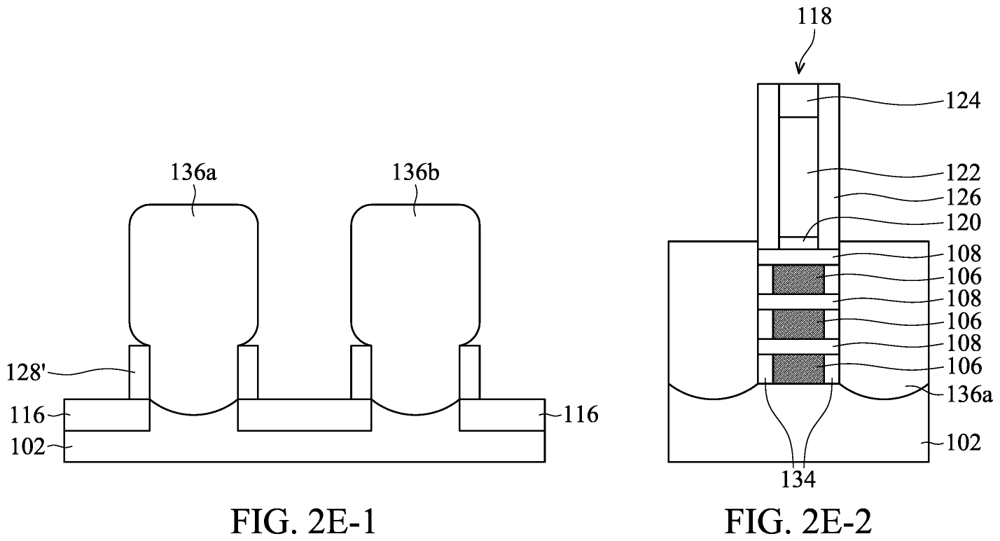

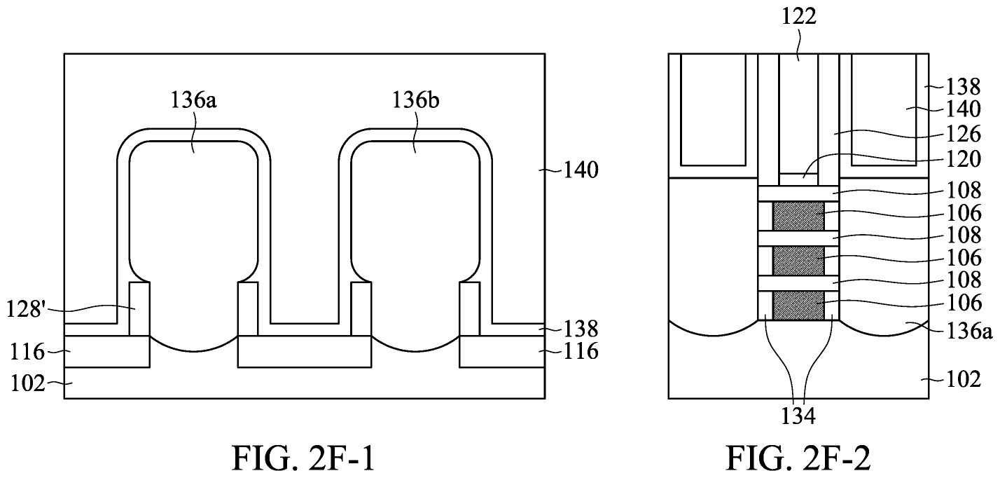

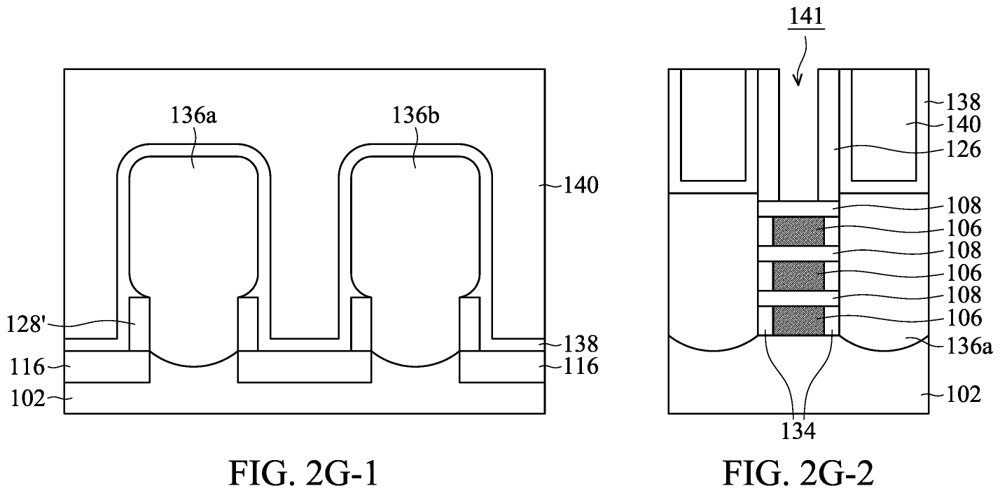

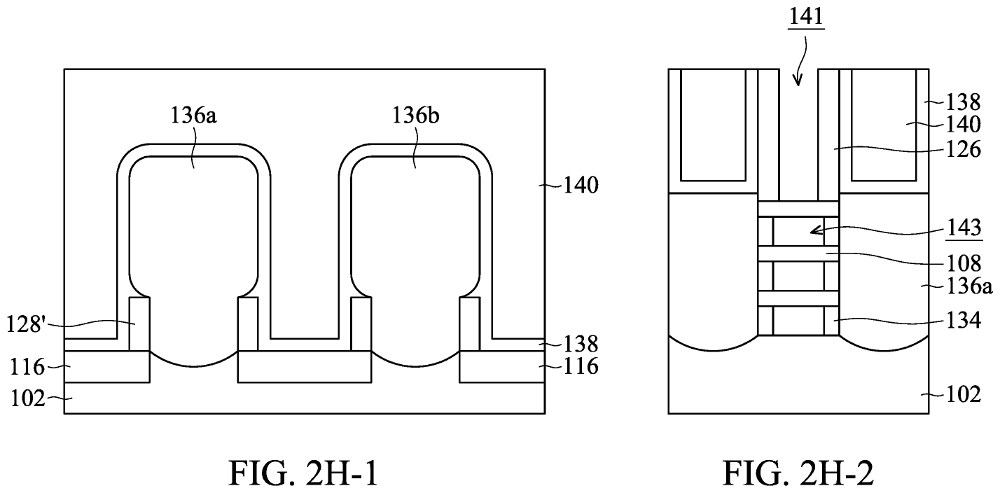

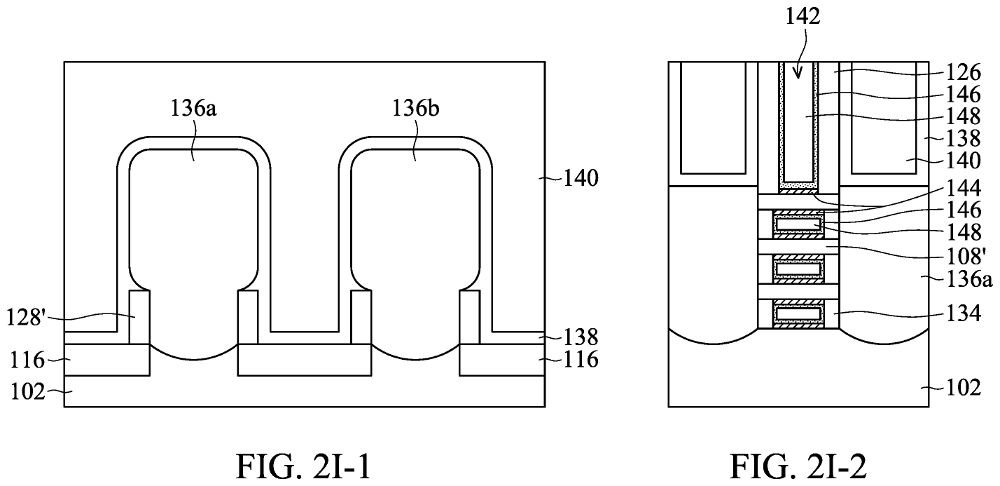

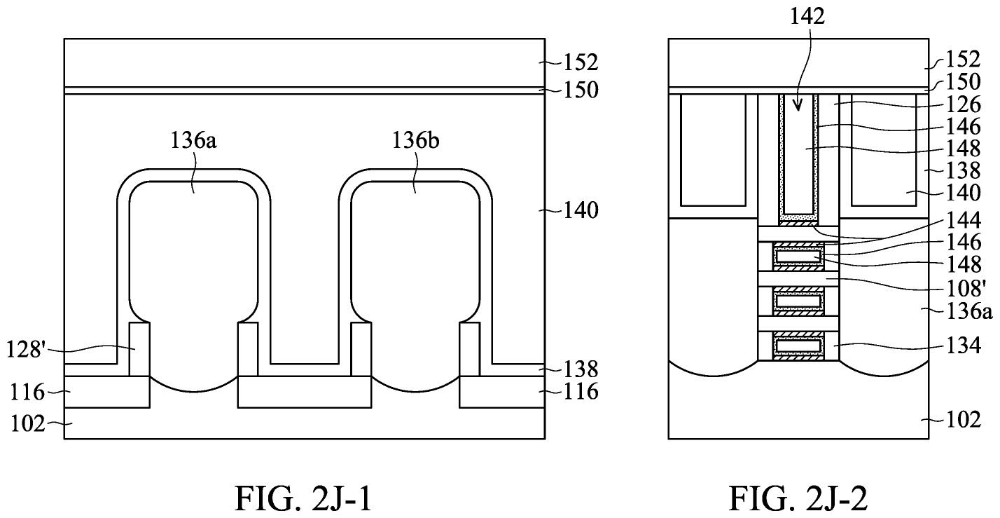

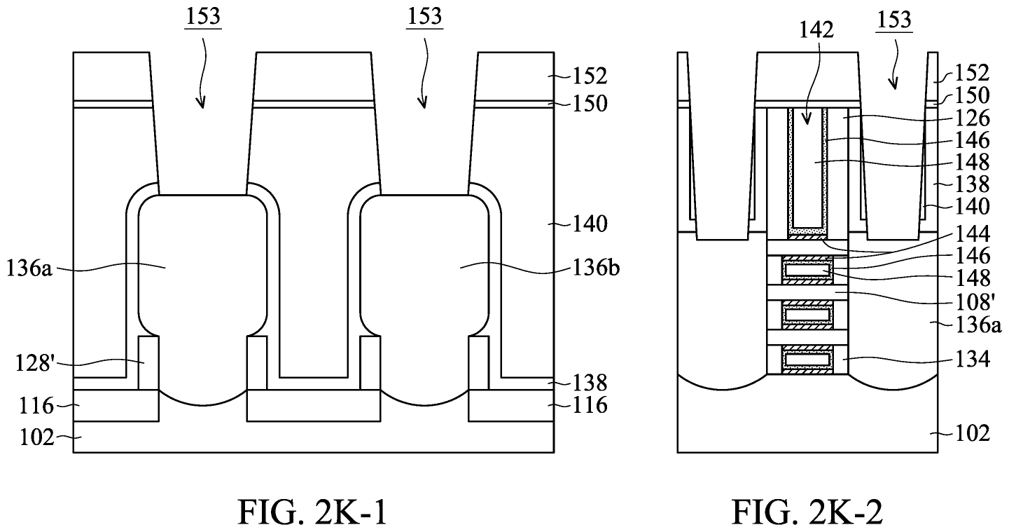

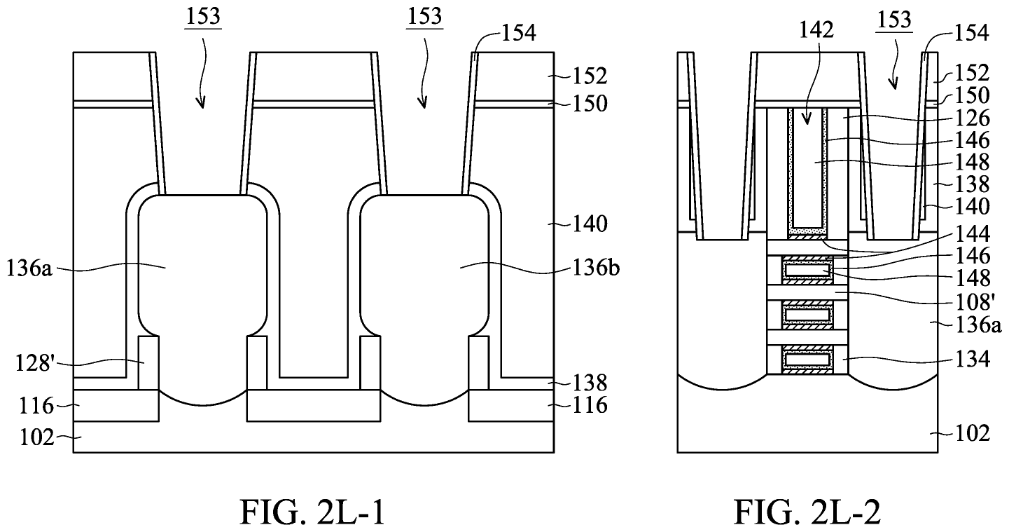

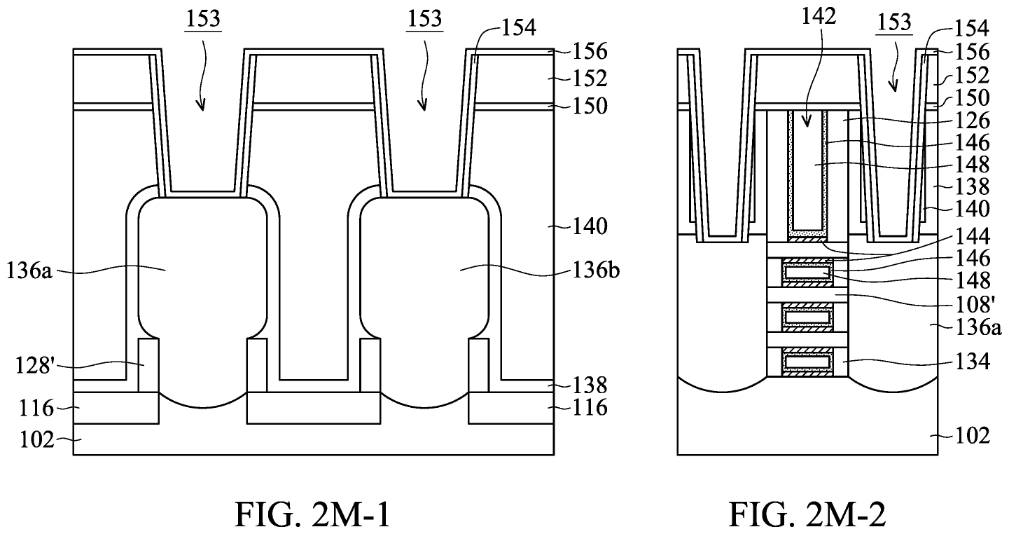

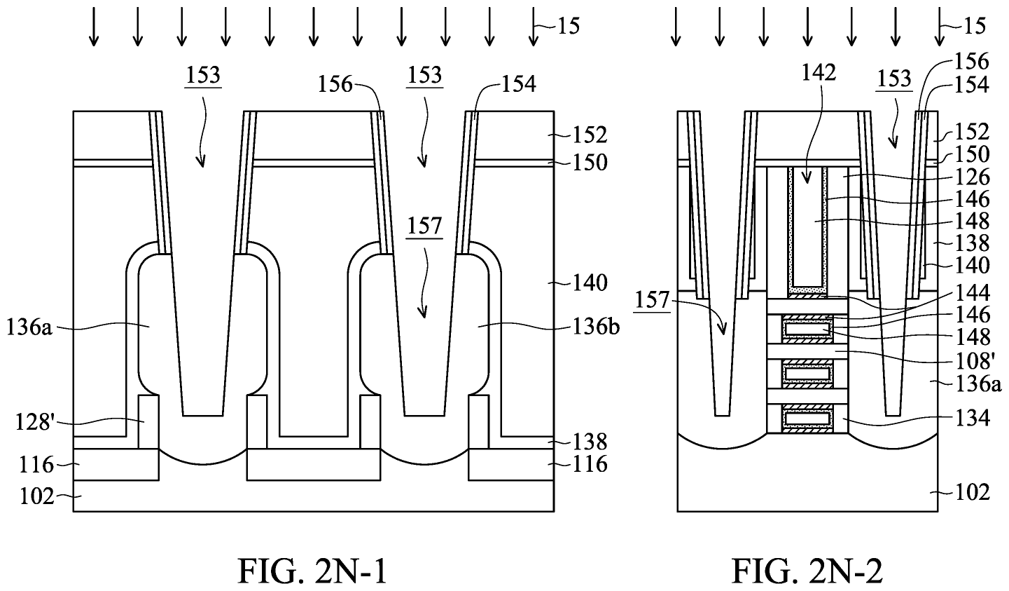

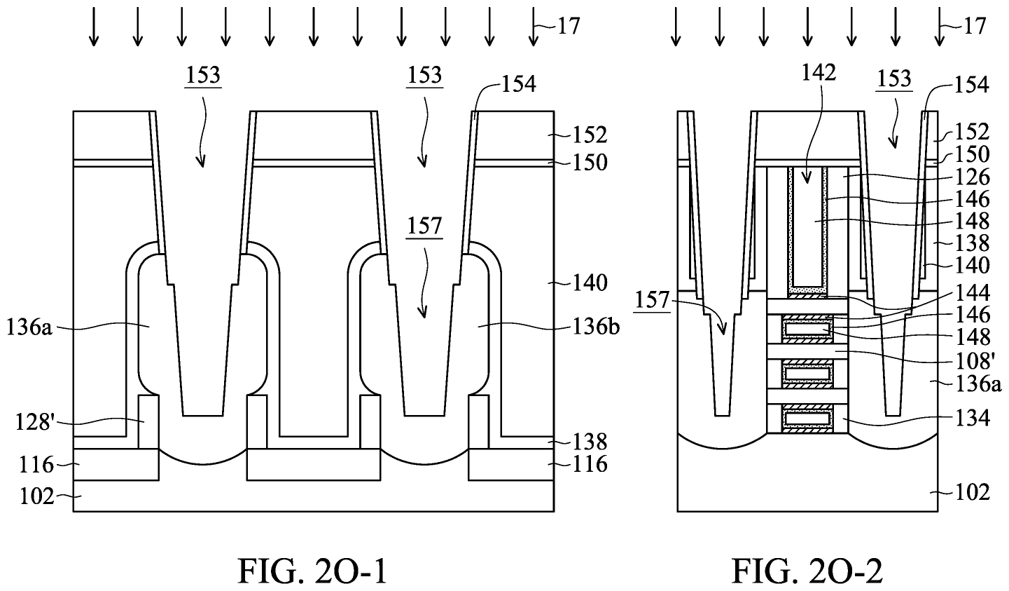

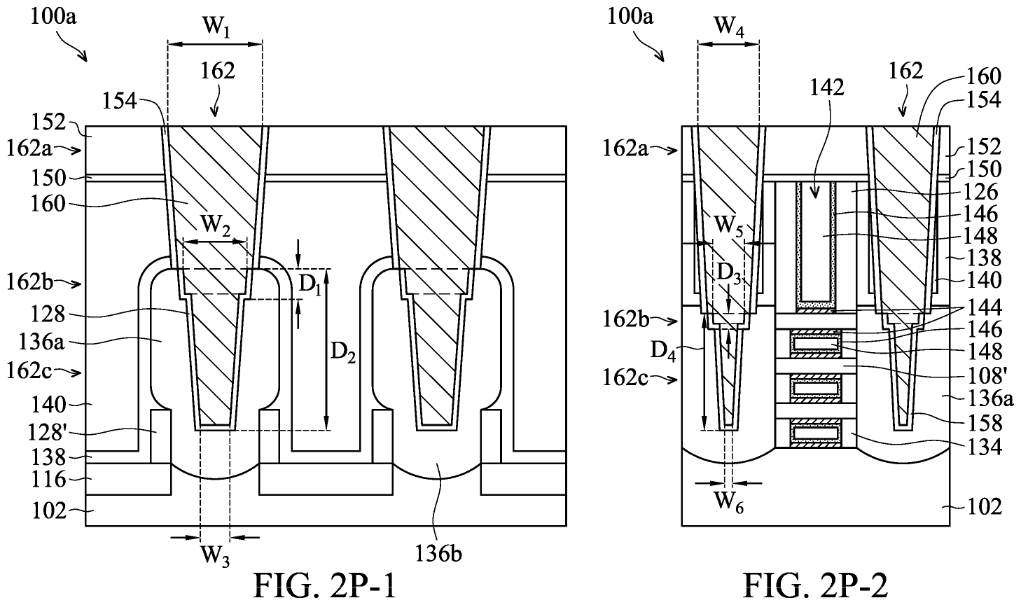

FIGS. 2A-1 to 2P-1 illustrate cross-sectional representations of various stages of manufacturing the semiconductor structure 100a shown along line A-A′ in FIG. 1E, in accordance with some embodiments. FIGS. 2A-2 to 2P-2 illustrate cross-sectional representations of various stages of manufacturing the semiconductor structure 100a shown along line B-B′ in FIG. 1E, in accordance with some embodiments.

More specifically, FIG. 2A-1 illustrates the cross-sectional representation shown along line A-A″ in FIG. 1E and FIG. 2A-2 illustrates the cross-sectional representation shown along line B-B′ in FIG. 1E in accordance with some embodiments.

As shown in FIGS. 2B-1 and 2B-2, after the gate spacer layers 126 and the fin spacer layers 128 are formed, the source/drain (S/D) regions of the fin structure 104 are recessed to form source/drain (S/D) recesses 130, as shown in in accordance with some embodiments. More specifically, the first semiconductor material layers 106 and the second semiconductor material layers 108 not covered by the dummy gate structures 118 and the gate spacer layers 126 are removed in accordance with some embodiments. In addition, some portions of the base fin structure 105 are also recessed to form curved top surfaces, as shown in FIG. 2B-1 in accordance with some embodiments.

In some embodiments, the fin structure 104 is recessed by performing an etching process. The etching process may be an anisotropic etching process, such as dry plasma etching, and the dummy gate structure 118 and the gate spacer layers 126 are used as etching masks during the etching process. In some embodiments, the fin spacer layers 128 are also recessed to form lowered fin spacer layers 128′.

Afterwards, as shown in FIGS. 2C-1 and 2C-2, after the source/drain (S/D) recesses 130 are formed, the first semiconductor material layers 106 exposed by the source/drain recesses 130 are laterally recessed to form notches 132, in accordance with some embodiments.

In some embodiments, an etching process is performed on the semiconductor structure 100 to laterally recess the first semiconductor material layers 106 of the fin structure 104 from the source/drain recesses 130. In some embodiments, during the etching process, the first semiconductor material layers 106 have a greater etching rate (or etching amount) than the second semiconductor material layers 108, thereby forming notches 132 between adjacent second semiconductor material layers 108. In some embodiments, the etching process is an isotropic etching such as dry chemical etching, remote plasma etching, wet chemical etching, another suitable technique, and/or a combination thereof.

Next, as shown in FIGS. 2D-1 and 2D-2, inner spacer layers 134 are formed in the notches 132 between the second semiconductor material layers 108, in accordance with some embodiments. The inner spacer layers 134 are configured to separate the source/drain (S/D) structures and the gate structures formed in subsequent manufacturing processes in accordance with some embodiments. In some embodiments, the inner spacer layers 134 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the inner spacer layer 134 is formed by a deposition process, such as chemical vapor deposition (CVD) process, atomic layer deposition (ALD) process, another applicable process, or a combination thereof.

Afterwards, as shown in FIGS. 2E-1 and 2E-2, after the inner spacer layers 134 are formed, a first source/drain (S/D) structure 136a and a second S/D structure 136b are formed in the S/D recesses 130, in accordance with some embodiments. In some embodiments, the first source/drain (S/D) structure 136a and the second S/D structure 136b are formed using an epitaxial growth process, such as Molecular beam epitaxy (MBE), Metal-organic Chemical Vapor Deposition (MOCVD), Vapor-Phase Epitaxy (VPE), other applicable epitaxial growth process, or a combination thereof. In some embodiments, the first source/drain (S/D) structure 136a and the second S/D structure 136b are made of any applicable material, such as Ge, Si, GaAs, AlGaAs, SiGe, GaAsP, SiP, SiC, SiCP, or a combination thereof.

In some embodiments, the first source/drain (S/D) structure 136a and the second S/D structure 136b are in-situ doped during the epitaxial growth process. For example, the first source/drain (S/D) structure 136a and the second S/D structure 136b may be the epitaxially grown SiGe doped with boron (B). For example, the first source/drain (S/D) structure 136a and the second S/D structure 136b may be the epitaxially grown Si doped with carbon to form silicon:carbon (Si:C) source/drain features, phosphorous to form silicon:phosphor (Si:P) source/drain features, or both carbon and phosphorous to form silicon carbon phosphor (SiCP) source/drain features. In some embodiments, the first source/drain (S/D) structure 136a and the second S/D structure 136b are doped in one or more implantation processes after the epitaxial growth process.

Next, as shown in FIGS. 2F-1 and 2F-2, after the first source/drain (S/D) structure 136a and the second S/D structure 136b are formed, a contact etch stop layer (CESL) 138 is conformally formed to cover the S/D structures 136 and an interlayer dielectric (ILD) layer 140 is formed over the contact etch stop layers 138, in accordance with some embodiments.

In some embodiments, the contact etch stop layer 138 is made of a dielectric materials, such as silicon nitride, silicon oxide, silicon oxynitride, another suitable dielectric material, or a combination thereof. The dielectric material for the contact etch stop layers 138 may be conformally deposited over the semiconductor structure by performing chemical vapor deposition (CVD), ALD, other application methods, or a combination thereof.

The ILD layer 140 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The ILD layer 140 may be formed by chemical vapor deposition (CVD), physical vapor deposition, (PVD), atomic layer deposition (ALD), or other applicable processes.

After the contact etch stop layer 138 and the ILD layer 140 are deposited, a planarization process such as CMP or an etch-back process may be performed until the gate electrode layers 120 of the dummy gate structures 118 are exposed, as shown in FIG. 2F-2 in accordance with some embodiments.

Afterwards, as shown in FIGS. 2G-1 and 2G-2, the dummy gate structure 118 is removed to form a trench 141, in accordance with some embodiments. As a result, the first stack structure 104a and the second stack structure 104b are exposed by the trench 141.

The removal process may include one or more etching processes. For example, when the dummy gate electrode layer 122 is polysilicon, a wet etchant such as a tetramethylammonium hydroxide (TMAH) solution may be used to selectively remove the dummy gate electrode layer 122. Afterwards, the dummy gate dielectric layer 120 may be removed using a plasma dry etching, a dry chemical etching, and/or a wet etching.

Next, as shown in FIGS. 2H-1 and 2H-2, the first semiconductor material layers 106 are removed to form nanostructures 108′ with the second semiconductor material layers 108, in accordance with some embodiments. The first S/D structure 132a and the second S/D structure 132b are attached to the nanostructures 108′. The first stack structure 104a and the second stack structure 104b includes the nanostructures 108′.

The first semiconductor material layers 106 may be removed by performing a selective wet etching process, such as APM (e.g., ammonia hydroxide-hydrogen peroxide-water mixture) etching process. For example, the wet etching process uses etchants such as ammonium hydroxide (NH₄OH), TMAH, ethylenediamine pyrocatechol (EDP), and/or potassium hydroxide (KOH) solutions.

Next, as shown in FIGS. 2I-1 and 2I-2, after the nanostructures 108′ are formed, a gate structure 142 is formed to surround the nanostructures 108′ and over the isolation structure 110, in accordance with some embodiments. More specifically, the dummy gate structures 118 and the first semiconductor material layers 106 are removed to form nanostructures 108′ with the second semiconductor material layers 108, in accordance with some embodiments. The S/D structure 136 is attached to the nanostructures 108′.

After the nanostructures 108′ are formed, the gate structure 142 is formed wrapped around the nanostructures 108′. The gate structure 142 wraps around the nanostructures 108′ to form gate-all-around transistor structures in accordance with some embodiments. In some embodiments, the gate structure 142 includes an interfacial layer 144, a gate dielectric layer 146, and a gate electrode layer 148.

In some embodiments, the interfacial layers 144 are oxide layers formed around the nanostructures 108′ and on the top of the base fin structure 105. In some embodiments, the interfacial layers 144 are formed by performing a thermal process.

In some embodiments, the gate dielectric layers 146 are formed over the interfacial layers 144, so that the nanostructures 108′ are surrounded (e.g. wrapped) by the gate dielectric layers 146. In addition, the gate dielectric layers 146 also cover the sidewalls of the gate spacer layers 126 and the inner spacer layers 134 in accordance with some embodiments. In some embodiments, the gate dielectric layers 146 are made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, another suitable high-k dielectric material, or a combination thereof. In some embodiments, the gate dielectric layers 146 are formed using chemical vapor deposition (CVD), atomic layer deposition (ALD), another applicable method, or a combination thereof.

In some embodiments, the gate structure 142 is formed on the gate dielectric layer 146. In some embodiments, the gate structure 142 is made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. In some embodiments, the gate structure 142 is formed using chemical vapor deposition (CVD), atomic layer deposition (ALD), electroplating, another applicable method, or a combination thereof. Other conductive layers, such as work function metal layers, may also be formed in the gate structure 142, although they are not shown in the figures. In some embodiments, the n-work function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAlN), tantalum carbon nitride (TaCN), tantalum silicon nitride (TaSiN), manganese (Mn), zirconium (Zr) or a combination thereof. In some embodiments, the p-work function layer includes titanium (Ti), titanium nitride (TiN), tantalum nitride (TaN), tantalum carbide (TaC), molybdenum nitride, tungsten nitride (WN), ruthenium (Ru) or a combination thereof.

After the interfacial layers 144, the gate dielectric layers 146, and the gate structure 142 are formed, a planarization process such as CMP or an etch-back process may be performed until the ILD layer 140 is exposed.

Afterwards, as shown in FIGS. 2J-1 and 2J-2, an etch stop layer 150 is formed over the gate structure 142, and a dielectric layer 152 is formed over the etch stop layer 150, in accordance with some embodiments.

In some embodiments, the etch stop layer 150 is made of a dielectric materials, such as silicon nitride, silicon oxide, silicon oxynitride, another suitable dielectric material, or a combination thereof. The dielectric material for the etch stop layers 150 may be conformally deposited over the semiconductor structure by performing chemical vapor deposition (CVD), ALD, other application methods, or a combination thereof.

The dielectric layer 152 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The dielectric layer 152 may be formed by chemical vapor deposition (CVD), physical vapor deposition, (PVD), atomic layer deposition (ALD), or other applicable processes.

Next, as shown in FIGS. 2K-1 and 2K-2, a portion of the ILD layer 140, a portion of the etch stop layer 150 and a portion of the dielectric layer 152 are removed to form openings 153, in accordance with some embodiments. As result, the top surface of the first S/D structure 136a and the top surface of the second S/D structure 136b are exposed.

The openings 153 may be formed using a photolithography process and an etching process. In addition, some portions of the first S/D structure 136a and second S/D structure 136b exposed by the contact openings may also be etched during the etching process.

Next, as shown in FIGS. 2L-1 and 2L-2, a barrier layer 154 is conformally formed in the openings 153, in accordance with some embodiments. Next, the bottom portion of the barrier layer is removed by an etching process to expose the top surface of the first S/D structure 136a and the top surface of the second S/D structure 136b.

In some embodiments, the barrier layer 154 is made of dielectric materials, such as silicon nitride, silicon oxide, SiCN, SiOCN, SiCO, AlOx, HfO, or high-k dielectric materials, or another applicable dielectric material. The barrier layer 154 is formed by performing chemical vapor deposition (CVD), atomic layer deposition (ALD), or another applicable process.

Next, as shown in FIGS. 2M-1 and 2M-2, a sacrificial layer 156 is formed on the barrier layer 154, in accordance with some embodiments. The sacrificial layer 156 and the barrier layer 154 are made of different materials. The barrier layer 154 has a high etching selectivity with respect to the sacrificial layer 156. When the sacrificial layer 156 are removed at the following steps, the barrier layer 154 is not removed or removed slightly.

In some embodiments, the sacrificial layer 156 is made of dielectric materials, such as silicon nitride, silicon oxide, AlOx, SiON, or another applicable dielectric material. In some embodiments, the sacrificial layer 156 is formed by chemical vapor deposition (CVD), atomic layer deposition (ALD), or another applicable process.

Next, as shown in FIGS. 2N-1 and 2N-2, a first etching process 15 is performed to remove a portion of the first S/D structure 136a and a portion of the second S/D structure 136b to form a trench 157, in accordance with some embodiments. The barrier layer 154 and the sacrificial layer 156 are used as a mask when performing the first etching process 15. The trench 157 has a sidewall surface without any turning point.

It should be noted that the bottom surface of the trench 157 is lower than the top surface of the first S/D structure 136a and the top surface of the second S/D structure 136b. In addition, the bottom surface of the trench 157 is lower than the topmost nanostructure 108′. In some other embodiments, the bottom surface of the trench 157 is lower than the bottommost nanostructure 108′.

In some other embodiments, the first etching process 15 is a dry etching process. In some other embodiments, the etchant used in the first etching process 15 includes fluorine (F)—containing gas, chlorine (Cl)—containing gas or another applicable gas.

Next, as shown in FIGS. 2O-1 and 2O-2, a second etching process 17 is performed to enlarge the trench 157, in accordance with some embodiments. Another portion of the first S/D structure 136a and another portion of the second S/D structure 136b are removed, and the sacrificial layer 156 is removed simultaneously. The width and the depth of the trench 157 are further increased by the second etching process 17. As a result, the trench 157 has a T-shaped structure. The sidewall surface of the trench 157 has a turning point after the second etching process 17.

After the second etching process 17, the bottommost surface of the trench 157 is lower than the top surface of the first S/D structure 136a and the top surface of the second S/D structure 136b. In addition, the bottommost surface of the trench 157 is lower than the bottommost nanostructure 108′. Furthermore, the bottommost surface of the trench 157 is lower than the top surface of the lowered fin spacer layers 128′.

Next, as shown in FIGS. 2P-1 and 2P-2, a metal silicide layer 158 and an S/D contact layer 160 are formed in the opening 153 and the trench 157, in accordance with some embodiments. An S/D contact structure 162 is formed by the metal silicide layer 158 and the S/D contact layer 160. The barrier layer 154 is not removed, the barrier layer 154 is formed on the sidewall surface of the S/D contact structure 162. The S/D contact structure 162 is surrounded by the barrier layer 154 to protect the S/D contact structure 162.

The metal silicide layers 158 may be formed by forming a metal layer over the top surfaces of the first S/D structure 136a and the second S/D structure 136b and annealing the metal layer so the metal layer reacts with the first S/D structure 136a and the second S/D structure 136b to form the metal silicide layers 158. The unreacted metal layer may be removed after the silicide layers 154 are formed.

In some embodiments, the S/D contact layer 160 is made of tungsten (W), ruthenium (Ru), molybdenum (Mo), or the like. In some embodiments, the S/D contact layer 160 is formed by performing a deposition process, such as chemical vapor deposition (CVD), physical vapor deposition, (PVD), atomic layer deposition (ALD), or other applicable processes.

As shown in FIG. 2P-1, the S/D contact structure 162 has a T-shaped structure with different widths from top to bottom. More specifically, the S/D contact structure 162 has a top portion 162a, a middle portion 162b and a bottom portion 162c. The dot line shown in FIG. 2P-1 is drawn to provide a better understanding of the structure, but there is no actual interface or boundary between the top portion 162a, the middle portion 162b and the bottom portion 162c. The middle portion 162b and the bottom portion 162c are embedded in the S/D structure 136a/136b. The top portion 162a is formed by filling materials into the opening 153, and the middle portion 162b and the bottom portion 162c are formed by filling materials into the trench 157. Since the trench 157 has a T-shaped structure, the middle portion 162b and the bottom portion 162c form the T-shaped structure.

The top surface of the top portion 162a has a first width W₁, the middle portion 162b has a second width W₂, and the bottom portion 162c has a bottom surface with a third width W₃. In some embodiments, the first width W₁ is greater than the second width W₂, and the second width W₂ is greater than the third width W₃. In some embodiments, the S/D contact structure 162 has a sidewall surface, and the sidewall surface has a step-shaped structure. In other words, the sidewall surface of the S/D contact structure 162 has two turning points.

As shown in FIG. 2P-1, the middle portion 162b has a first depth D₁ measured from the top surface of the S/D structure 136a/136b to the interface between the middle portion 162b and the bottom portion 162c (the interface is a turning point), and the bottom portion 162c has a second depth D₂. The second depth D₂ is greater than the first depth D₁.

As shown in FIG. 2P-2, the top portion 162a has a top surface with a fourth width W₄, the middle portion 162b has a fifth width W₅, and the bottom portion 162c has a bottom surface with a sixth width W₆. In some embodiments, the fourth width W₄ is greater than the fifth width W₅, and the fifth width W₅ is greater than the sixth width W₆. In some embodiments, the difference between the second width W₂ and the third width W₃ is substantially the same width the difference between the fifth width W₅ and the sixth width W₆. In some embodiments, the difference between the fifth width W₅ and the sixth width W₆ is greater than the difference between the second width W₂ and the third width W₃.

As shown in FIG. 2P-1, the middle portion 162b has a third depth D₃ measured from the top surface of the S/D structure 136a/136b to the interface between the middle portion 162b and the bottom portion 162c (the interface is a turning point), and the bottom portion 162c has a fourth depth D₄. The fourth depth D₄ is greater than the third depth D₃.

Furthermore, the metal silicide layer 158 also has step-shaped structure. The bottommost surface of the metal silicide layer 158 is lower than the topmost nanostructure 108′. In some embodiments, the bottommost surface of the metal silicide layer 158 is lower than the bottommost nanostructure 108′.

The bottommost surface of the S/D contact structure 162 is lower than the topmost nanostructure 108′. In some embodiments, the bottommost surface of the S/D contact structure 162 is lower than the bottommost nanostructure 108′ In some embodiments, the bottommost surface of the S/D contact structure 162 is lower than the topmost inner spacer layer 134.

It should be noted that the S/D contact structure 162 is formed by two etching processes, rather than by one etching process, the opening 153 and the trench 157 are formed by different steps, and therefore the aspect ratio is reduced when forming the trench 157. The lower aspect ratio is used to help the filling the contact materials for forming the S/D contact structure 162. In addition, the contact area between the/D contact structure 162 and the S/D structure 136a/136b is increased by forming the T-shaped structure S/D contact structure 162. Therefore, the contact resistance between the S/D contact structure 162 and the S/D structure 136a/136b is reduced.

Furthermore, the T-shaped S/D contact structure 162 is in direct contact with the central portion 136C of the S/D structure 136a/136b, and is separated from the sidewall portion 136S of the S/D structure 136a/136b. Therefore, the contact resistance between the S/D contact structure 162 and the S/D structure 136a/136b is reduced. Therefore, the performance of the semiconductor structure 100a is improved.

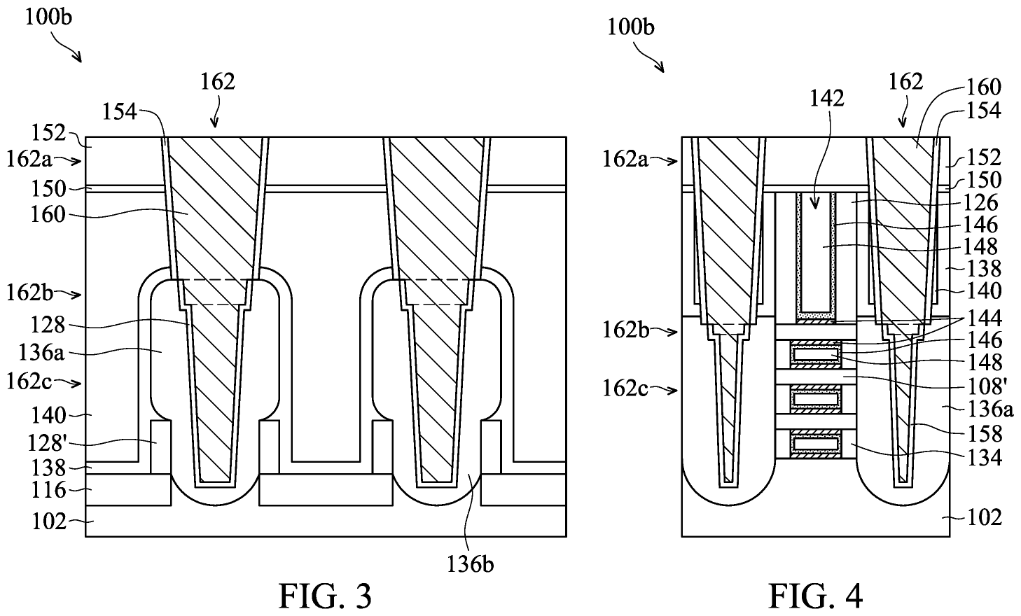

FIG. 3 illustrates a cross-sectional view of a semiconductor structure 100b along line A-A′ in FIG. 1E, in accordance with some embodiments. FIG. 4 illustrates a cross-sectional view of the semiconductor structure 100b along line B-B′ in FIG. 1E, in accordance with some embodiments.

The semiconductor structure 100b of FIGS. 3 and 4 includes elements that are similar to, or the same as, elements of the semiconductor structure 100a of FIGS. 2A-1 to 2P-1 and 2A-2 to 2P-2, the difference between the FIGS. 3 and 4 and FIGS. 2P-1 and 2P-2 is that the depth of the trench 157 is increased, and the length of the bottom portion 162c of the S/D contact structure 162 is increased. As a result, the bottommost surface of the S/D contact structure 162 is lower than bottommost nanostructure 108′. In some embodiments, the bottommost surface of the S/D contact structure 162 is lower than the top surface of the isolation structure 116. In some embodiments, the bottommost surface of the S/D contact structure 162 is lower than the top surface of the lowered fin spacer layers 128′.

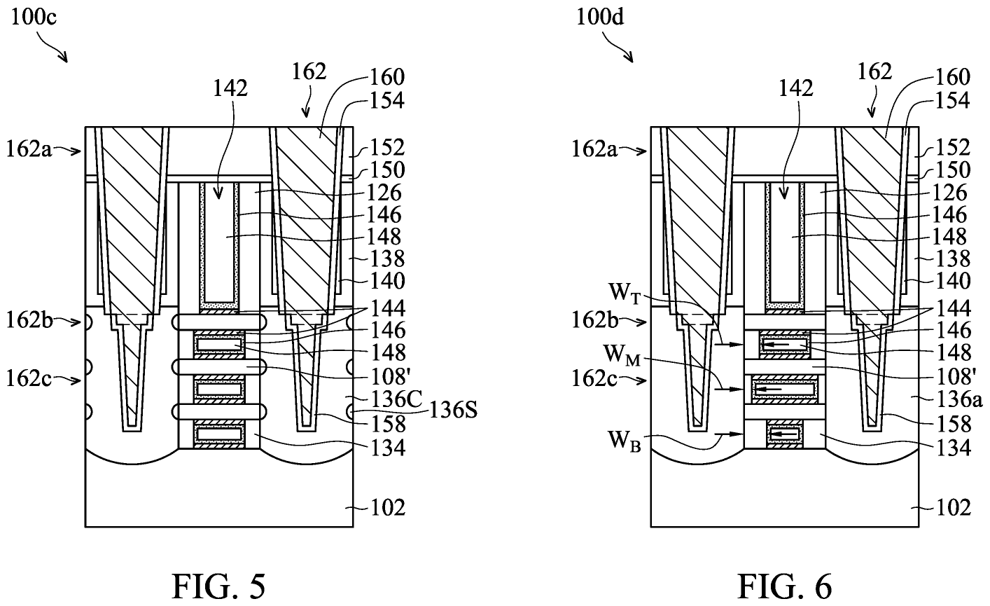

FIG. 5 illustrates a cross-sectional view of a semiconductor structure 100c, in accordance with some embodiments. The semiconductor structure 100b of FIG. 5 includes elements that are similar to, or the same as, elements of the semiconductor structure 100a of FIGS. 2A-1 to 2P-1 and 2A-2 to 2P-2, the difference between the FIG. 5 and FIGS. 2P-1 and 2P-2 is that the S/D structure 136a/136b includes the sidewall portion 136S and the central portion 136C, the sidewall portion 136S is formed firstly when forming the S/D structure 136a/136b and is in direct contact with the nanostructures 108′. Since the inner spacer layers 134 are not made of semiconductor materials, and therefore when forming the S/D structure 136a/136b, the sidewall portion 136S is not formed on the inner spacer layers 134. The boundary of the sidewall portion 136S is in direct contact with the interface between the nanostructures 108′ and the inner spacer layers 134.

The first doping concentration of the sidewall portion 136S is smaller than a second doping concentration of the central portion 136C. The S/D contact structure 162 is separated from the sidewall portion 136S of the S/D structure 136a/136b by the central portion 136C. Since the S/D contact structure 162 is not in direct contact with the sidewall portion 136S of the S/D structure 136a/136b, the contact resistance between the S/D contact structure 162 and the S/D structure 136a/136b is reduced.

FIG. 6 illustrates a cross-sectional view of a semiconductor structure 100d, in accordance with some embodiments. The semiconductor structure 100d of FIG. 6 includes elements that are similar to, or the same as, elements of the semiconductor structure 100a of FIGS. 2A-1 to 2P-1 and 2A-2 to 2P-2, the difference between the FIG. 6 and FIGS. 2P-1 and 2P-2 is that the widths of the each of the inner spacer layers 134 are different due to the process control.

In some embodiments, there are three levels of the inner spacer layers 134. The first level of the inner spacer layers 134 has a width W_{B}. The second level of the inner spacer layers 134 has a width W_{M}. The third level of the inner spacer layers 134 has a width W_{T}. In some embodiments, the width W_{B} is greater than the width W_{T}, and the width W_{T} is greater than the width W_{M}.

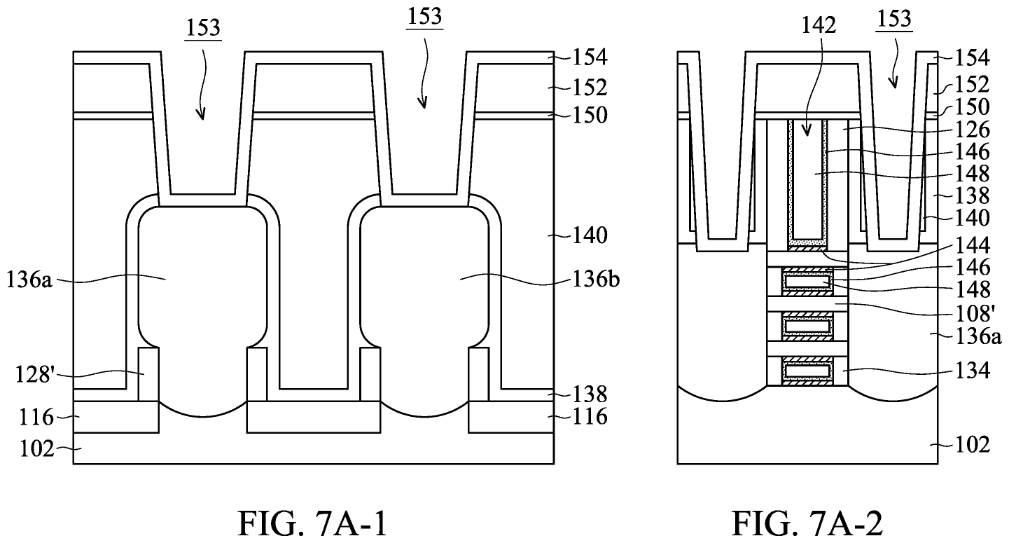

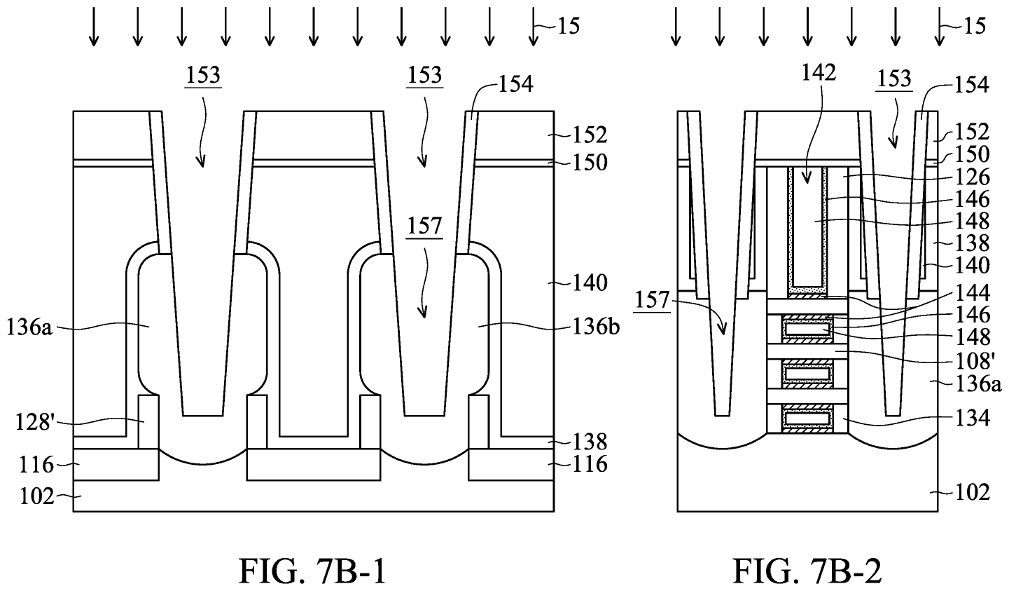

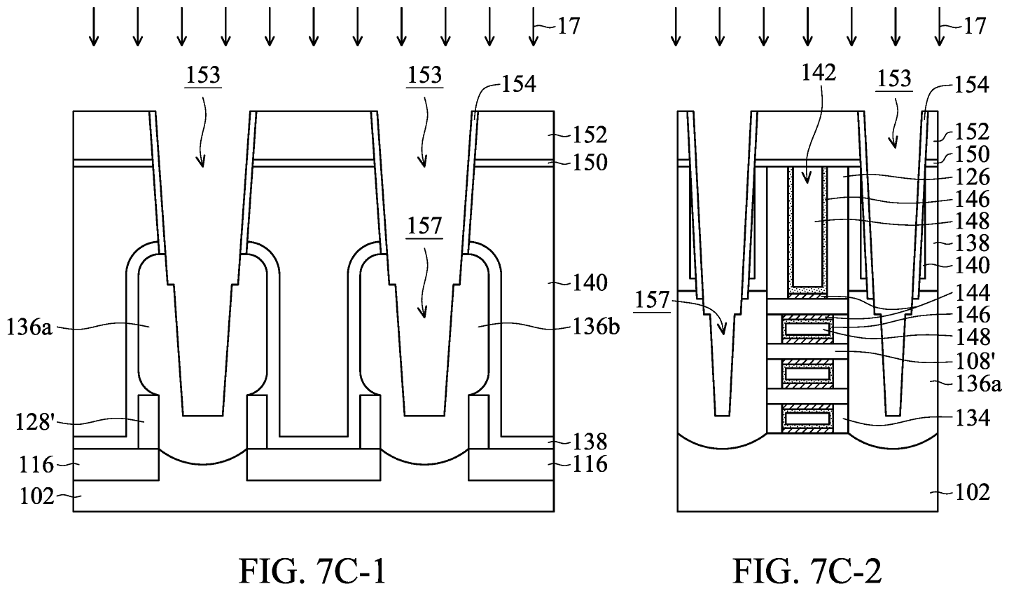

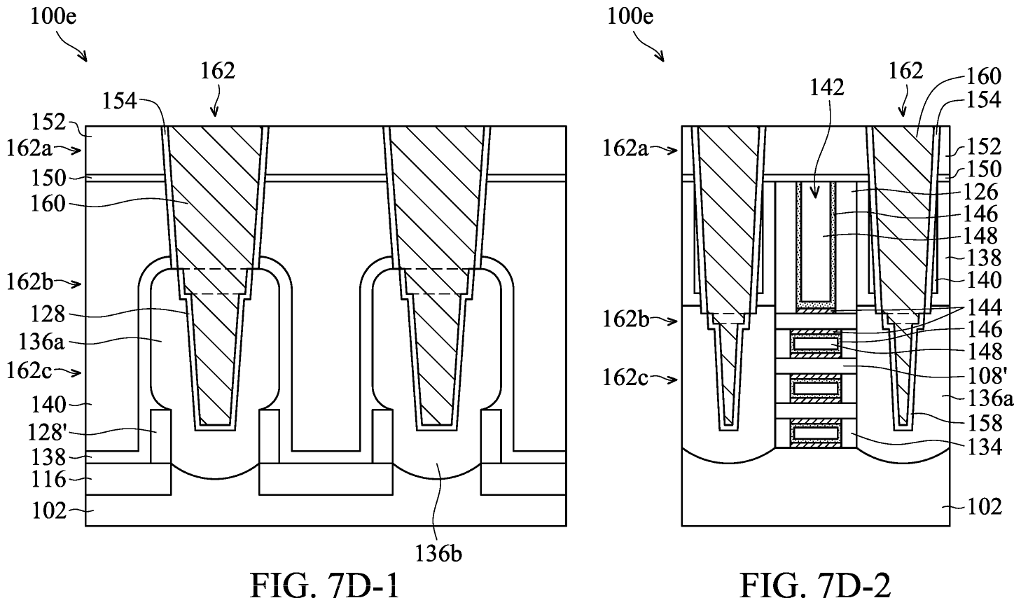

FIGS. 7A-1 to 7D-1 illustrate cross-sectional representations of various stages of manufacturing a semiconductor structure 100e shown along line A-A′ in FIG. 1E, in accordance with some embodiments. FIGS. 7A-2 to 7D-2 illustrate cross-sectional representations of various stages of manufacturing the semiconductor structure 100e shown along line B-B′ in FIG. 1E, in accordance with some embodiments. The semiconductor structure 100e of FIGS. 7A-1 to 7D-1 and 7A-2 to 7D-2 includes elements that are similar to, or the same as, elements of the semiconductor structure 100a of FIGS. 2A-1 to 2P-1 and 2A-2 to 2P-2.

As shown in FIGS. 7A-1 and 7A-2, the barrier layer 154 is formed on the sidewall surface and the bottom surface of the opening 153. The thickness of the barrier layer 154 shown in FIGS. 7A-1 and 7A-2 is thicker than the thickness of the barrier layer 154 shown in FIGS. 2L-1 and 2L-2.

In some embodiments, the barrier layer 154 is made of dielectric materials, such as silicon nitride, silicon oxide, SiCN, SiOCN, SiCO, AlOx, HfO, or high-k dielectric materials, or another applicable dielectric material. The barrier layer 154 is formed by performing chemical vapor deposition (CVD), atomic layer deposition (ALD), or another applicable process.

Next, as shown in FIGS. 7B-1 and 7B-2, the first etching process 15 is performed to remove a portion of the first S/D structure 136a and a portion of the second S/D structure 136b to form a trench 157, in accordance with some embodiments. The trench 157 has a sidewall surface without any turning point. The barrier layer 154 is used as a mask when performing the first etching process 15.

It should be noted that the bottom surface of the trench 157 is lower than the top surface of the first S/D structure 136a and the top surface of the second S/D structure 136b. In addition, the bottom surface of the trench 157 is lower than the topmost nanostructure 108′. In some other embodiments, the bottom surface of the trench 157 is lower than the bottommost nanostructure 108′.

After wards, as shown in FIGS. 7C-1 and 7C-2, the second etching process 17 is performed to enlarge the trench 157, in accordance with some embodiments. Another portion of the first S/D structure 136a and another portion of the second S/D structure 136b are removed, and the sacrificial layer 156 is removed simultaneously. The width and the depth of the trench 157 are further increased by the second etching process 17. As a result, the trench 157 has a T-shaped structure. The sidewall surface of the trench 157 has a turning point after the second etching process 17.

After the second etching process 17, the bottommost surface of the trench 157 is lower than the top surface of the first S/D structure 136a and the top surface of the second S/D structure 136b. In addition, the bottommost surface of the trench 157 is lower than the bottommost nanostructure 108′. Furthermore, the bottommost surface of the trench 157 is lower than the top surface of the lowered fin spacer layers 128′.

Next, as shown in FIGS. 7D-1 and 7D-2, the metal silicide layer 158 and the S/D contact layer 160 are formed in the opening 153 and the trench 157, in accordance with some embodiments. The S/D contact structure 162 is formed by the metal silicide layer 158 and the S/D contact layer 160. The barrier layer 154 is still formed on the sidewall surface of the S/D contact structure 162.

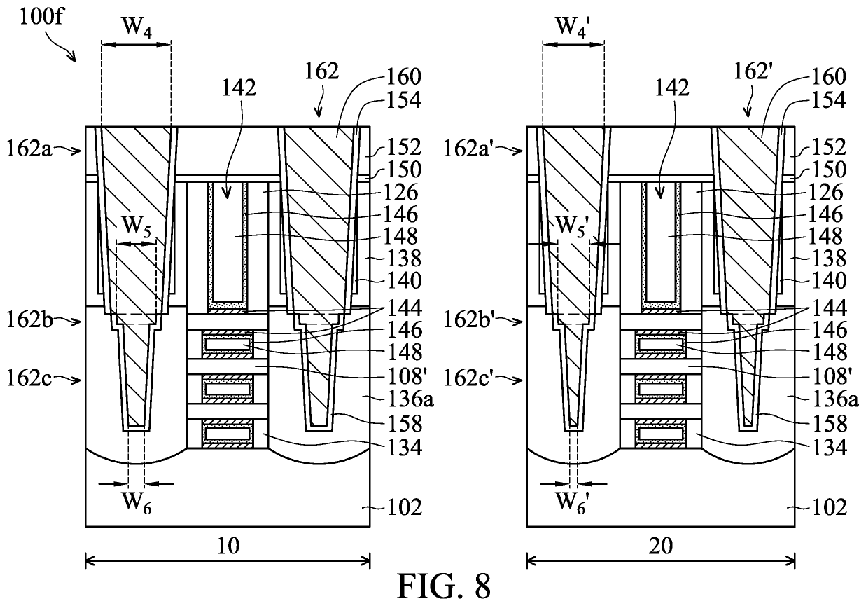

FIG. 8 illustrates a cross-sectional view of a semiconductor structure 100f, in accordance with some embodiments. The semiconductor structure 100f of FIG. 8 includes elements that are similar to, or the same as, elements of the semiconductor structure 100a of FIGS. 2A-1 to 2P-1 and 2A-2 to 2P-2.

As shown in FIG. 8, there are first region 10 and the second region 20. The S/D contact structure 162 is formed in the first region 10, and the S/D contact structure 162′ is formed in the second region 20. The semiconductor structure in the first region 10 may be NMOS, and the semiconductor structure formed in the second region 20 may be PMOS.

In some embodiments, the fourth width W₄′ of the top portion 162′a of the S/D contact structure 162′ in the second region 20 may be smaller than the fourth width W₄ of the top portion 162a of the S/D contact structure 162 in the first region 10. In some embodiments, the fifth width W₅′ of the middle portion 162′b of the S/D contact structure 162′ in the second region 20 may be smaller than the fifth width W₅ of the top portion 162a of the S/D contact structure 162 in the first region 10. In some embodiments, the sixth width W₆′ of the bottom portion 162′c of the S/D contact structure 162′ in the second region 20 may be smaller than the sixth width W₆ of the bottom portion 162a of the S/D contact structure 162 in the first region 10.

Each of the semiconductor structures 100a to 100f has S/D contact structure 162 with T-shaped structure having turning points in sidewall surface. The contact resistance between the S/D contact structure 162 and the S/D contact structure 136a/136b is reduced. Therefore, the performance of the semiconductor structure is improved.

It should be appreciated that the semiconductor structures 100a to 100f having S/D contact structure 162 with T-shaped structure described above may also be applied to FinFET structures, although not shown in the figures.

It should be noted that same elements in FIGS. 1A to 8 may be designated by the same numerals and may include similar or the same materials and may be formed by similar or the same processes; therefore such redundant details are omitted in the interest of brevity. In addition, although FIGS. 1A to 8 are described in relation to the method, it will be appreciated that the structures disclosed in FIGS. 1A to 8 are not limited to the method but may stand alone as structures independent of the method. Similarly, although the methods shown in FIGS. 1A to 8 are not limited to the disclosed structures but may stand alone independent of the structures. Furthermore, the nanostructures described above may include nanowires, nanosheets, or other applicable nanostructures in accordance with some embodiments.

Also, while disclosed methods are illustrated and described below as a series of acts or events, it will be appreciated that the illustrated ordering of such acts or events may be altered in some other embodiments. For example, some acts may occur in different orders and/or concurrently with other acts or events apart from those illustrated and/or described above. In addition, not all illustrated acts may be required to implement one or more aspects or embodiments of the description above. Further, one or more of the acts depicted above may be carried out in one or more separate acts and/or phases.

Furthermore, the terms “approximately,” “substantially,” “substantial” and “about” describe above account for small variations and may be varied in different technologies and be in the deviation range understood by the skilled in the art. For example, when used in conjunction with an event or circumstance, the terms can refer to instances in which the event or circumstance occurs precisely as well as instances in which the event or circumstance occurs to a close approximation.

Embodiments for forming semiconductor structures may be provided. The semiconductor structure includes a gate structure formed over the nanostructures and an S/D structure adjacent to the gate structure. An S/D contact structure is formed on the S/D structure, and a portion of the S/D contact structure is embedded into the S/D structure. The S/D contact structure is formed by two step etching process to form an opening and a T-shaped trench, and the contact materials formed in the opening and T-shaped trench. Since the/D contact structure is formed by two step etching process, the aspect ratio is recued to help the filling the contact materials. In addition, the contact area between the/D contact structure and the S/D structure is increased by forming the T-shaped structure S/D contact structure 162. The contact resistance between the S/D contact structure and the S/D structure is reduced. Therefore, the performance of the semiconductor structure is improved.

In some embodiments, a semiconductor structure is provided. The semiconductor structure includes nanostructures formed over a substrate, and a gate structure formed on the nanostructures. The semiconductor structure includes a source/drain (S/D) structure formed adjacent to the gate structure. The semiconductor structure includes a contact structure formed on the S/D structure, and a portion of the contact structure is embedded in the S/D structure, and the contact structure has a T-shaped structure.

In some embodiments, a semiconductor structure is provided. The semiconductor structure includes first nanostructures formed over a first region of a substrate, and a first gate structure formed on the first nanostructures. The semiconductor structure includes a first source/drain (S/D) structure formed adjacent to the first gate structure. The semiconductor structure includes a first contact structure formed on the first S/D structure, and the first contact structure has a sidewall surface, and the sidewall surface has a step-shaped structure with turning points.

In some embodiments, a method for forming a semiconductor structure is provided. The method includes forming a fin structure over a substrate, and the fin structure comprise first semiconductor material layers and second semiconductor material layers alternately stacked. The method includes removing a portion of the fin structure to form an S/D recess, and forming an S/D structure in the S/D recess. The method also includes forming a dielectric layer over the S/D structure, and forming an opening to expose a top surface of the S/D structure. The method includes forming a barrier layer in the opening, and performing a first etching process to form a trench in the S/D structure. The method includes performing a second etching process to enlarge the trench, wherein the trench has a T-shaped structure. The method includes forming a contact structure in the trench, and a bottom surface of the contact structure is lower than a top surface of the S/D structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
nanostructures formed over a substrate;
a gate structure formed on the nanostructures;
a source/drain (S/D) structure formed adjacent to the gate structure; and
a contact structure formed on the S/D structure, wherein a portion of the contact structure is embedded in the S/D structure, and the contact structure has a T-shaped structure.

2. The semiconductor structure as claimed in claim 1, wherein a bottom surface of the contact structure is lower than a topmost surface of the nanostructures.

3. The semiconductor structure as claimed in claim 1, wherein the contact structure has a bottom surface with a bottom width and a top surface with a top width, and the top width is greater than the bottom width.

4. The semiconductor structure as claimed in claim 1, further comprising:
an isolation structure formed over the substrate, wherein a bottommost surface of the contact structure is lower than a top surface of the isolation structure.

5. The semiconductor structure as claimed in claim 1, further comprising:
a barrier layer formed on a sidewall surface of the contact structure.

6. The semiconductor structure as claimed in claim 1, wherein the S/D structure comprises a sidewall portion and a central portion, the sidewall portion is in direct contact with the nanostructures, a first doping concentration of the sidewall portion is smaller than a second doping concentration of the central portion, and the contact structure is separated from the sidewall portion by the central portion.

7. The semiconductor structure as claimed in claim 1, further comprising:
a metal silicide layer formed between the S/D structure and the contact structure, wherein a bottommost surface of the metal silicide layer is lower than a bottommost nanostructure.

8. The semiconductor structure as claimed in claim 7, wherein the metal silicide layer has a step-shaped structure.

9. The semiconductor structure as claimed in claim 1, further comprising:
a plurality of inner spacer layers formed between the gate structure and the S/D structure, wherein a bottommost surface of the contact structure is lower than a topmost inner spacer layer.

10. A semiconductor structure, comprising:
first nanostructures formed over a first region of a substrate;
a first gate structure formed on the first nanostructures;
a first source/drain (S/D) structure formed adjacent to the first gate structure; and
a first contact structure formed on the first S/D structure, wherein the first contact structure has a sidewall surface, and the sidewall surface has a step-shaped structure with turning points.

11. The semiconductor structure as claimed in claim 10, wherein the S/D structure comprises a sidewall portion and a central portion, the sidewall portion is in direct contact with the first nanostructures, a first doping concentration of the sidewall portion is smaller than a second doping concentration of the central portion, and the first contact structure is separated from the sidewall portion by the central portion.

12. The semiconductor structure as claimed in claim 10, wherein the first contact structure has a top portion, a middle portion and a bottom portion, the top portion has a top surface with a first width, the middle portion has a second width, and the bottom portion has a bottom surface with a third width, and the first width is greater than the second width, and the second width is greater than the third width.

13. The semiconductor structure as claimed in claim 10, wherein a bottommost surface of the first contact structure is lower than a bottommost first nanostructure.

14. The semiconductor structure as claimed in claim 10, further comprising:
a metal silicide layer formed between the first S/D structure and the first contact structure, wherein the metal silicide layer has a step-shaped structure.

15. The semiconductor structure as claimed in claim 14, further comprising:
a fin spacer layer formed adjacent to the first S/D structure, wherein a bottommost surface of the metal silicide layer is lower than a top surface of the fin spacer layer.

16. The semiconductor structure as claimed in claim 10, further comprising:
second nanostructures formed over a second region of the substrate;
a second source/drain (S/D) structure formed adjacent to the second nanostructures; and
a second contact structure formed on the second S/D structure, wherein a bottom surface of the second contact structure has a second width, and a bottom surface of the first contact structure has a first width, and the second width is smaller than the first width.

17. A method for forming a semiconductor structure, comprising:
forming a fin structure over a substrate, wherein the fin structure comprises first semiconductor material layers and second semiconductor material layers alternately stacked;
removing a portion of the fin structure to form an S/D recess;
forming an S/D structure in the S/D recess;
forming a dielectric layer over the S/D structure;
forming an opening to expose a top surface of the S/D structure;
forming a barrier layer in the opening;
performing a first etching process to form a trench in the S/D structure;
performing a second etching process to enlarge the trench, wherein the trench has a T-shaped structure; and
forming a contact structure in the trench, wherein a bottom surface of the contact structure is lower than a top surface of the S/D structure.

18. The method for forming the semiconductor structure as claimed in claim 17, further comprising:
forming a metal silicide layer between the S/D structure and the contact structure, wherein the metal silicide layer has a step-shaped structure.

19. The method for forming the semiconductor structure as claimed in claim 17, further comprising:
forming a sacrificial layer on the spacer layer in the opening; and
removing the sacrificial layer when performing the second etching process.

20. The method for forming the semiconductor structure as claimed in claim 17, further comprising:
removing the first semiconductor material layers to form nanostructures; and
forming a gate structure on the nanostructures, wherein a bottommost surface of the contact structure is lower than a bottommost first nanostructure.
